(19) United States
(12) Patent Application Publication
(10) Pub. No.: US 2017/0271368 A1
(43) Pub. Date: Sep. 21, 2017

(54) DISPLAY SUBSTRATE, MANUFACTURING METHOD FOR THE SAME, AND DISPLAY DEVICE

(71) Applicants: BOE TECHNOLOGY GROUP CO., LTD., Beijing (CN); BEIJING BOE OPTOELECTRONICS TECHNOLOGY CO., LTD., Beijing (CN)

(72) Inventors: Pengju Zhang, Beijing (CN); Xin Li, Beijing (CN); Xuchen Yuan, Beijing (CN)

(21) Appl. No.: 15/228,537

(22) Filed: Aug. 4, 2016

(30) Foreign Application Priority Data
Mar. 18, 2016 (CN) 201610158377.9

(51) Int. Cl. H01L 27/12

(52) U.S. Cl. CPC H01L 27/124; H01L 27/1248; H01L 27/1259

(57) ABSTRACT

The embodiments of the disclosure provide a display substrate, a manufacturing method for the same, and a display device. The display substrate comprises a base substrate and a plurality of electrically conductive layers insulated from one another on the base substrate, wherein each of at least two of the plurality of electrically conductive layers insulated from one another includes a ground wire, and each ground wire is grounded.

### CROSS REFERENCE TO RELATED APPLICATIONS

This application claims the benefit and priority of Chinese Patent Application No. 201610158377.9 filed on Mar. 18, 2016. The entire disclosure of the above application is incorporated herein by reference.

### BACKGROUND

The embodiments of the disclosure relate to a display substrate, a manufacturing method for the same, and a display device.

As display technology continues to develop, display devices are widely used in the display field. A display device generally includes a display panel. Antistatic capability is one of the indexes for evaluating working performance and reliability of the display panel, and is also a premise for the display panel to operate stably.

The display panel typically includes a display substrate. FIG. 1 shows a structural diagram of a display substrate 00 in the prior art. Referring to FIG. 1, the display panel 00 includes a base substrate 001. A patterned gate metal layer 002, a gate insulating layer 003, a patterned semiconductor layer 004, a patterned source/drain metal layer 005, an intermediate insulating layer 006 and a pixel electrode 007 are sequentially formed on the base substrate 001. The patterned gate metal layer 002 includes a gate electrode 0021, a peripheral signal line 0022 and a gate line (not shown in FIG. 1) connected with the gate electrode 0021. The patterned source/drain metal layer 005 includes a source electrode 0051, a drain electrode 0052, a peripheral signal line 0053 and a data line (not shown in FIG. 1) connected with the source electrode 0051. A via is formed in the intermediate insulating layer 006, and the pixel electrode 007 is connected with the drain electrode 0052 through the via. The peripheral signal line may include a common electrode line, a test line, a power line, wiring of a drive circuit and so forth. Wirings in the patterned gate metal layer 002 have a region overlapping with wirings in the patterned source/drain metal layer 005 (an orthographic projection of the wirings in the patterned gate metal layer 002 onto the base substrate 001 have regions overlapping with an orthographic projection of the wirings in the patterned source/drain metal layer 005 onto the base substrate 001). External static electricity may enter the inside of the display substrate 00 from its periphery. When static electricity is generated in the overlapping regions of the wirings in the patterned gate metal layer 002 and the wirings in the patterned source/drain metal layer 005, the static electricity may easily break down an insulating layer between the patterned gate metal layer 002 and the patterned source/drain metal layer 005, such that the wirings in the patterned gate metal layer 002 and the wirings in the patterned source/drain metal layer 005 are connected and a short circuit occurs. Accordingly, as shown in FIG. 1, a ground wire 0023 located in the same layer as the gate electrode 0021 may be formed in a peripheral region of the display substrate 00. When external static electricity enters the display substrate 00, the ground wire 0023 can guide the static electricity into the earth to avoid the breakdown of the insulating layer, improving antistatic capability of the display substrate and of the display panel.

However, the ground wire and the gate electrode are provided in the same layer in the prior art, so it is impossible to guide the static electricity completely, and as a consequence, the display substrate has a poor antistatic capability.

### BRIEF DESCRIPTION

The embodiments of the disclosure provide a display substrate, a manufacturing method for the same, and a display device.

A first aspect of the embodiments of the disclosure provides a display substrate, comprising:

a base substrate, and

a plurality of electrically conductive layers insulated from one another on the base substrate, wherein each of at least two of the plurality of electrically conductive layers insulated from one another includes a ground wire, and each ground wire is grounded.

In an exemplary embodiment, the ground wire in each of the at least two electrically conductive layers is grounded individually.

In an exemplary embodiment, all ground wires in the at least two electrically conductive layers are connected with one another, and one ground wire in the at least two electrically conductive layers is grounded.

In an exemplary embodiment, the display substrate further comprises:

an insulating layer between every two adjacent electrically conductive layers of the at least two electrically conductive layers, ground wires in the at least two electrically conductive layers being connected with one another through a via formed in the insulating layer.

In an exemplary embodiment, the at least two electrically conductive layers include a patterned gate metal layer and a patterned source/drain metal layer, the patterned gate metal layer being located on the base substrate and including a gate electrode,

wherein the display substrate further comprises:

a gate insulating layer on the patterned gate metal layer and the base substrate; and

a patterned semiconductor layer on the gate insulating layer,

and wherein the patterned source/drain metal layer is located on the patterned semiconductor layer and the gate insulating layer, and includes a source electrode and a drain electrode which are not in contact with each other but are both in contact with the patterned semiconductor layer, none of the source electrode, the drain electrode and the patterned semiconductor layer being in contact with a ground wire in the patterned source/drain metal layer.

In an exemplary embodiment, the at least two electrically conductive layers further include a patterned pixel electrode layer,

wherein the display substrate further comprises:

an intermediate insulating layer on the patterned semiconductor layer, the patterned source/drain metal layer and the gate insulating layer, the intermediate insulating layer having a drain via formed therein,

and wherein the patterned pixel electrode layer is located on the intermediate insulating layer and includes a pixel electrode connected with the drain electrode through the drain via.

In an exemplary embodiment, all ground wires in the at least two electrically conductive layers are located in a peripheral region of the display substrate, while the gate electrode, the patterned semiconductor layer, the source electrode, the drain electrode and the pixel electrode are all located in a display region of the display substrate.

In an exemplary embodiment, in the at least two electrically conductive layers, an orthographic projection of the via in the insulting layer on each electrically conductive layer onto the base substrate has a region overlapping with an orthographic projection of the ground wire in the each electrically conductive layer onto the base substrate.

In an exemplary embodiment, in the at least two electrically conductive layers, the orthographic projection of the via in the insulting layer on each electrically conductive layer onto the base substrate is in a region of the orthographic projection of the ground wire in the each electrically conductive layer onto the base substrate.

In an exemplary embodiment, each of the electrically conductive layers includes a peripheral signal line in a peripheral region of the display substrate.

A second aspect of the embodiments of the disclosure provides a manufacturing method for a display substrate, comprising:

forming a plurality of electrically conductive layers insulated from one another on a base substrate, wherein each of at least two of the plurality of electrically conductive layers insulated from one another includes a ground wire, and each ground wire is grounded.

In an exemplary embodiment, the ground wire in each of the at least two electrically conductive layers is grounded individually.

In an exemplary embodiment, all ground wires in the at least two electrically conductive layers are connected with one another, and one ground wire in the at least two electrically conductive layers is grounded.

In an exemplary embodiment, the manufacturing method further comprises:

forming an insulating layer between every two adjacent electrically conductive layers of the at least two electrically conductive layers, and forming a via in the insulating layer, ground wires in the at least two electrically conductive layers being connected with one another through the via.

In an exemplary embodiment, the at least two electrically conductive layers include a patterned gate metal layer and a patterned source/drain metal layer, the patterned gate metal layer being formed on the base substrate and including a gate electrode,

wherein the manufacturing method further comprises:

forming a gate insulating layer on the patterned gate metal layer and the base substrate; and

forming a patterned semiconductor layer on the gate insulating layer,

and wherein the patterned source/drain metal layer is formed on the patterned semiconductor layer and the gate insulating layer, and includes a source electrode and a drain electrode which are not in contact with each other but are both in contact with the patterned semiconductor layer, none of the source electrode, the drain electrode and the patterned semiconductor layer being in contact with a ground wire in the patterned source/drain metal layer.

In an exemplary embodiment, the at least two electrically conductive layers further include a patterned pixel electrode layer,

wherein the manufacturing method further comprises:

forming an intermediate insulating layer on the patterned semiconductor layer, the patterned source/drain metal layer, and the gate insulating layer; and

forming a drain via in the intermediate insulating layer,

and wherein the patterned pixel electrode layer is formed on the intermediate insulating layer and includes a pixel electrode connected with the drain electrode through the drain via.

In an exemplary embodiment, all ground wires in the at least two electrically conductive layers are located in a peripheral region of the display substrate, while the gate electrode, the patterned semiconductor layer, the source electrode, the drain electrode and the pixel electrode are all located in a display region of the display substrate.

A third aspect of the embodiments of the disclosure provides a display device including the display substrate according to the first aspect.

As described above, the embodiments of the disclosure provide a display substrate, a manufacturing method for the same, and a display device. The display substrate comprises a base substrate and a plurality of electrically conductive layers insulated from one another on the base substrate, wherein each of at least two of the plurality of electrically conductive layers insulated from one another includes a ground wire, and each ground wire is grounded. Thus, static electricity can be guided to the earth via ground wires in at least two electrically conductive layers, which improves antistatic capability of the display substrate and thereby improves antistatic capability of the display panel and the display device including the display substrate.

It will be appreciated that the aforesaid general description and the following detailed description are merely exemplary and do not limit the disclosure.

### BRIEF DESCRIPTION OF THE DRAWINGS

In order to illustrate the disclosure more clearly, a brief introduction to the drawings of the embodiments is made as follows. Obviously, the following drawings only relate to some embodiments of the disclosure, and do not limit the disclosure.

FIG. 1 is a structural diagram of a display substrate in the prior art;

FIG. 2 is a structural diagram of a display substrate provided in embodiments of the disclosure;

FIG. 3 is a structural diagram of another display substrate provided in embodiments of the disclosure;

FIG. 4 is a flowchart illustrating a manufacturing method for a display substrate provided in embodiments of the disclosure;

FIG. 5A is a structural diagram after forming a patterned gate metal layer on a base substrate according to an embodiment of the disclosure;

FIG. 5B is a structural diagram after forming a gate insulating layer on the patterned gate metal layer and the base substrate according to the embodiment of the disclosure;

FIG. 5C is a structural diagram after forming a first via in the gate insulating layer according to the embodiment of the disclosure;

FIG. 5D is a structural diagram after forming a patterned semiconductor layer in the gate insulating layer according to the embodiment of the disclosure;

FIG. 5E is a structural diagram after forming a patterned source/drain metal layer in the patterned semiconductor layer and the gate insulating layer according to the embodiment of the disclosure;

FIG. 5F is a structural diagram after forming an intermediate insulating layer on the patterned semiconductor layer, the patterned source/drain metal layer and the gate insulating layer according to the embodiment of the disclosure; and

FIG. 5G is a structural diagram after forming a second via and a drain via in the intermediate insulating layer according to the embodiment of the disclosure.

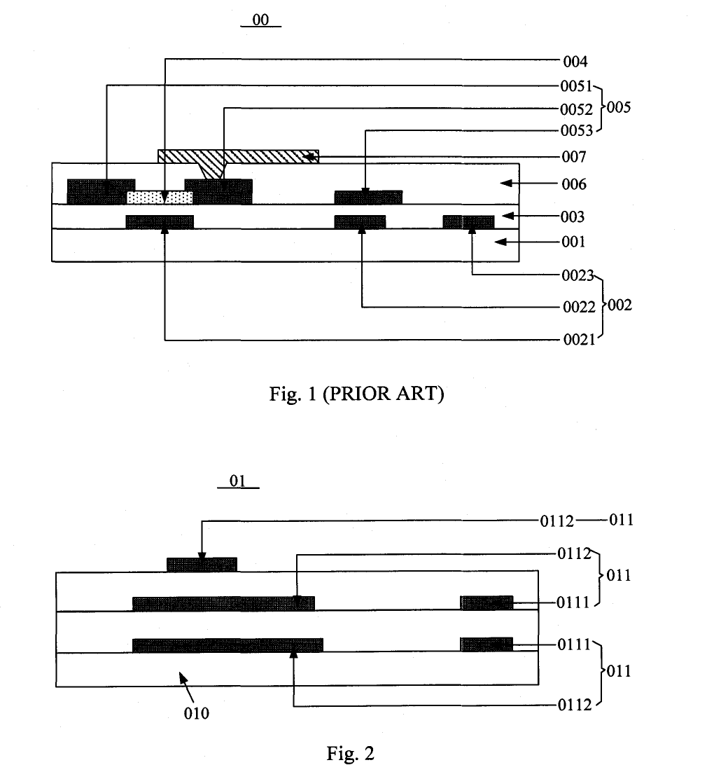

### DETAILED DESCRIPTION

In order to make the disclosure clearer, a clear and complete description of the disclosure will be made in conjunction with drawings of the embodiments of the disclosure. The embodiments to be described below are only some of embodiments, not all the embodiments. Based on the described embodiments of the disclosure, all other embodiments obtained by those skilled in the art without creative labor shall fall within the protection scope of the disclosure.

In the description to the embodiments of the disclosure, it is to be noted that directional or positional relations indicated by the terms “upper”, “lower”, “top”, “bottom” and the like are directional or positional relations shown in the drawings. These terms are used to merely facilitate the description to the embodiments of the disclosure and to simplify the description, but do not indicate or suggest that corresponding devices or elements must have specific directions and positions, or must be structured or operated in the specific directions and positions. Thus, those terms should not be considered to limit the disclosure.

FIG. 2 is a structural diagram of a display substrate 01 provided in embodiments of the disclosure. Referring to FIG. 2, the display substrate 01 comprises a base substrate 010.

A plurality of electrically conductive layers 011 insulated from one another are formed on the base substrate 010. As shown in FIG. 2, each of at least two of the plurality of electrically conductive layers 011 insulated from one another includes a ground wire 0112, and each ground wire 0112 is grounded.

In the display substrate provided by the embodiments of the disclosure, each of at least two electrically conductive layers includes a ground wire and each ground wire is grounded, so static electricity may be guided to the earth via ground wires in at least two electrically conductive layers, which improves antistatic capability of the display substrate and thereby improves antistatic capability of the display panel and the display device including the display substrate.

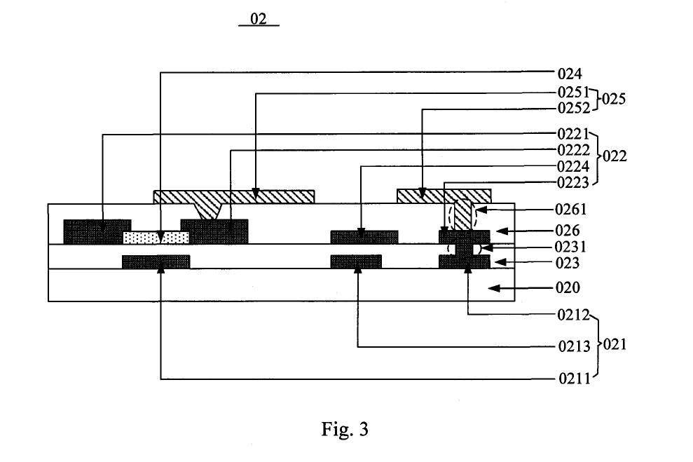

FIG. 3 is a structural diagram of another display substrate 02 provided in embodiments of the disclosure. Referring to FIG. 3, the display substrate 02 includes a base substrate 020.

A plurality of electrically conductive layers insulated from one another are formed on the base substrate 020. As shown in FIG. 3, each of at least two of the plurality of electrically conductive layers insulated from one another includes a ground wire, and each ground wire is grounded.

In an exemplary embodiment, the ground wire in each of at least two electrically conductive layers is grounded individually.

In another exemplary embodiment, all ground wires in at least two electrically conductive layers are connected with one another, and one ground wire in at least two electrically conductive layers is grounded. As an example, an insulating layer is formed between every two adjacent electrically conductive layers of the at least two electrically conductive layers, and ground wires in the at least two electrically conductive layers are connected with one another through a via formed in the insulating layer.

In an exemplary embodiment, as shown in FIG. 3, the at least two electrically conductive layers include a patterned gate metal layer 021 and a patterned source/drain metal layer 022. The patterned gate metal layer 021 is located on the base substrate 020 and includes a gate electrode 0211 and a first ground wire 0212. The display substrate in the embodiment may further comprise: a gate insulating layer 023 on the patterned gate metal layer 021 and the base substrate 020, a first via 0231 being formed in the gate insulating layer 023; and a patterned semiconductor layer 024 on the gate insulating layer 023. The patterned source/drain metal layer 022 is formed on the patterned semiconductor layer 024 and the gate insulating layer 023, and includes a source electrode 0221, a drain electrode 0222 and a second ground wire 0223. The source electrode 0221 and the drain electrode 0222 are not in contact with each other but are both in contact with the patterned semiconductor layer 024. None of the source electrode 0221, the drain electrode 0222 and the patterned semiconductor layer 024 is in contact with a ground wire in the patterned source/drain metal layer 022 (i.e., the second ground wire 0223). The second ground wire 0223 is connected with the first ground wire 0212 through the first via 0231.

Further, still referring to FIG. 3, the at least two electrically conductive layers may further include a patterned pixel electrode layer 025. The display substrate in present embodiment may further include: an intermediate insulating layer 026 on the patterned semiconductor layer 024, the patterned source/drain metal layer 022, and the gate insulating layer 023, and a drain via (not numbered in FIG. 3) and a second via 0261 are formed in the intermediate insulating layer 26. The patterned pixel electrode layer 025 is located on the intermediate insulating layer 026 and includes a pixel electrode 0251 and a third ground wire 0252. The pixel electrode 0251 is connected with the drain electrode 0222 through the drain via, and the third ground wire 0252 is connected with the second ground wire 0223 through the second via 0261.

In an exemplary embodiment, the display substrate 02 may include a display region and a peripheral region. All ground wires in the at least two electrically conductive layers are located in the peripheral region of the display substrate 02. As an example, as shown in FIG. 3, the first ground wire 0212, the second ground wire 0223 and the third ground wire 0252 are all located in the peripheral region of the display substrate 02, whereas the gate electrode 0211, the patterned semiconductor layer 024, the source electrode 0221, the drain electrode 0222 and the pixel electrode 0251 are all located in the display region of the display substrate 02.

In an exemplary embodiment, in the at least two electrically conductive layers, an orthographic projection of the via in the insulting layer on each electrically conductive layer onto the base substrate 020 has a region overlapping with an orthographic projection of the ground wire in the each electrically conductive layer onto the base substrate 020. Preferably, in the at least two electrically conductive layers, the orthographic projection of the via in the insulting layer on each electrically conductive layer onto the base substrate 020 is in a region of the orthographic projection of the ground wire in the each electrically conductive layer onto the base substrate 020. As an example, as shown in FIG. 3, an orthographic projection of the first via 0231 onto the base substrate 020 is within a region of an orthographic projection of the first ground wire 0212 onto the base substrate 020, and an orthographic projection of the second via 0261 onto the base substrate 020 is within the region of an orthographic projection of the second ground wire 0223 onto the base substrate 020.

In an exemplary embodiment, each of the electrically conductive layers includes a peripheral signal line in a peripheral region of the display substrate 02. As an example, as shown in FIG. 3, the patterned gate metal layer 021 may further include a peripheral signal line 0213, and the patterned source/drain metal layer 022 may further include a peripheral signal line 0224. Both the peripheral signal line 0213 and the peripheral signal line 0224 are located in the peripheral region of the display substrate 02.

To sum up, in the display substrate provided by the embodiments of the disclosure, each of at least two of the plurality of electrically conductive layers includes a ground wire and each ground wire is grounded, so static electricity can be guided to the earth via ground wires in the at least two electrically conductive layers, which improves antistatic capability of the display substrate and thereby improves antistatic capability of the display panel and the display device including the display substrate.

In the display substrate provided by the embodiments of the disclosure, a ground wire is formed in each electrically conductive layer, ground wires in all electrically conductive layers are connected with one another, and one ground wire is grounded, such that all the ground wires form an electrostatic shielding ring covering the display substrate at the periphery of the display substrate. This electrostatic shielding ring can effectively shield static electricity to improve antistatic capability of the display substrate and thereby improves antistatic capability of the display panel and the display device including the display substrate.

In the display substrate provided by the embodiments of the disclosure, the ground wire in each electrically conductive layer and other conductors (e.g. gate electrode) in the same electrically conductive layer may be formed through a same patterning process, which can reduce manufacturing processes and save manufacturing cost. Furthermore, ground wires in the embodiments of the disclosure are located in the peripheral region of the display substrate, so a blank region at the periphery of the substrate can be used to provide a maximum area of shielding net, thereby improving antistatic capability.

The embodiments of the disclosure further provide a manufacturing method for a display substrate such as the display substrate shown in FIG. 2 or FIG. 3, and comprising:

forming a plurality of electrically conductive layers insulated from one another on a base substrate, wherein each of at least two of the plurality of electrically conductive layers insulated from one another includes a ground wire, and each ground wire is grounded.

In an exemplary embodiment, the ground wire in each of the at least two electrically conductive layers is grounded individually.

In another exemplary embodiment, all ground wires in the at least two electrically conductive layers are connected with one another, and one ground wire in the at least two electrically conductive layers is grounded.

In an exemplary embodiment, the manufacturing method may further comprise:

forming an insulating layer between every two adjacent electrically conductive layers of the at least two electrically conductive layers, and forming a via in the insulating layer, ground wires in the at least two electrically conductive layers being connected with one another through the via.

In an exemplary embodiment, the at least two electrically conductive layers include a patterned gate metal layer and a patterned source/drain metal layer,

the patterned gate metal layer being formed on the base substrate and including a gate electrode,

wherein the manufacturing method further comprises:

forming a gate insulating layer on the patterned gate metal layer and the base substrate; and

forming a patterned semiconductor layer on the gate insulating layer,

and wherein the patterned source/drain metal layer is formed on the patterned semiconductor layer and the gate insulating layer, and includes a source electrode and a drain electrode which are not in contact with each other but are both in contact with the patterned semiconductor layer, none of the source electrode, the drain electrode and the patterned semiconductor layer being in contact with a ground wire in the patterned source/drain metal layer.

In an exemplary embodiment, the at least two electrically conductive layers further include a patterned pixel electrode layer,

wherein the manufacturing method further comprises:

forming an intermediate insulating layer on the patterned semiconductor layer, the patterned source/drain metal layer, and the gate insulating layer; and

forming a drain via in the intermediate insulating layer,

and wherein the patterned pixel electrode layer is formed on the intermediate insulating layer and includes a pixel electrode connected with the drain electrode through the drain via.

In an exemplary embodiment, all ground wires in the at least two electrically conductive layers are located in a peripheral region of the display substrate, while the gate electrode, the patterned semiconductor layer, the source electrode, the drain electrode and the pixel electrode are all located in a display region of the display substrate.

To sum up, according to the manufacturing method for a display substrate provided by the embodiments of the disclosure, each of at least two of the plurality of electrically conductive layers includes a ground wire and each ground wire is grounded, so static electricity can be guided to the earth via ground wires in the at least two electrically conductive layers, which improves antistatic capability of the display substrate and thereby improves antistatic capability of the display panel and the display device including the display substrate.

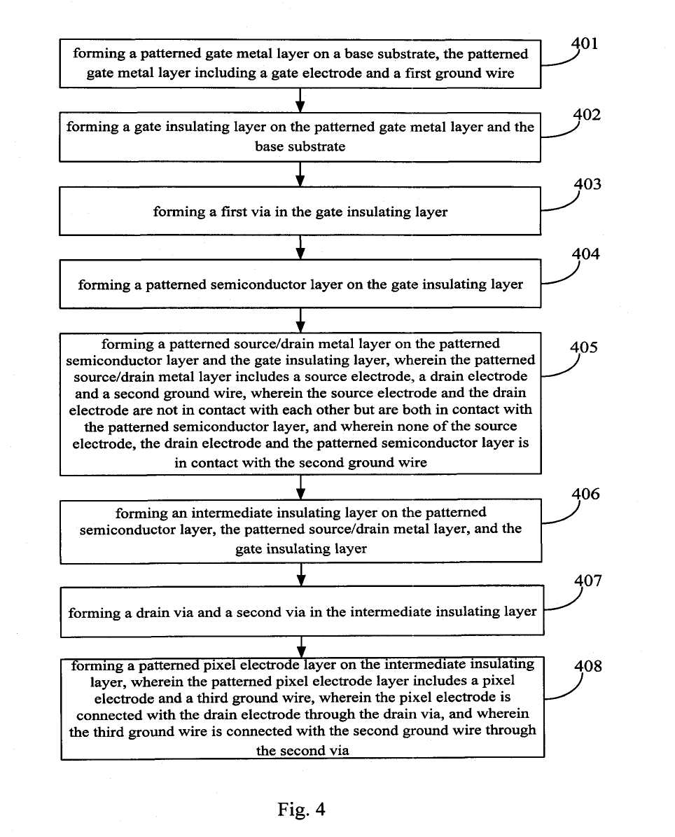

FIG. 4 shows a flowchart illustrating a manufacturing method for a display substrate provided by an embodiment of the disclosure. This embodiment of the disclosure is described by taking the manufacture of the display substrate 02 shown in FIG. 3 as an example. Referring to FIG. 4, the manufacturing method for a display substrate comprises the following steps 401-408:

Step 401: forming a patterned gate metal layer on a base substrate, the patterned gate metal layer including a gate electrode and a first ground wire.

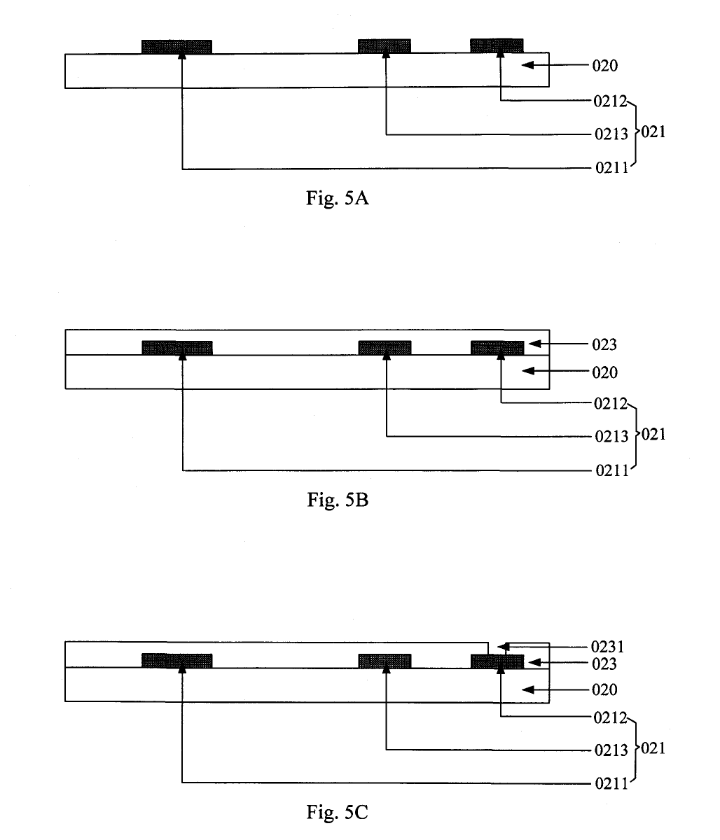

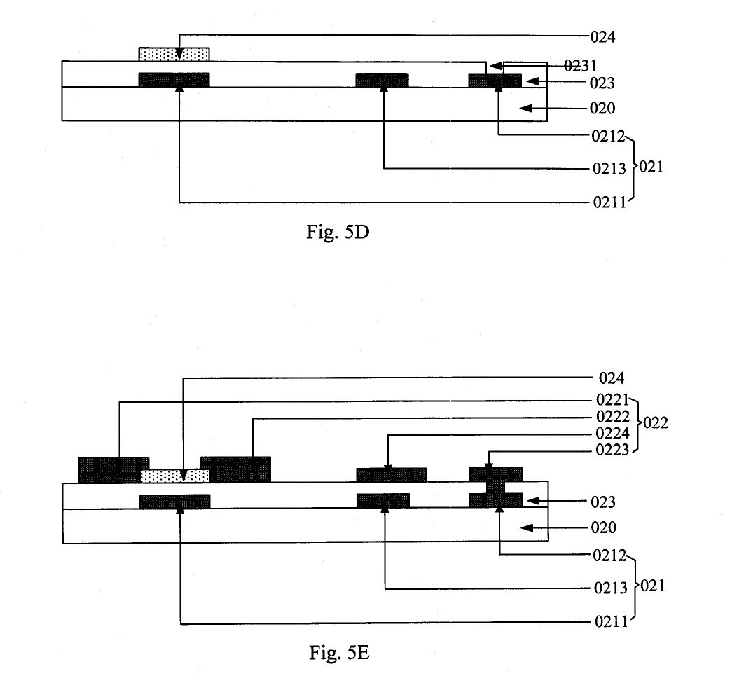

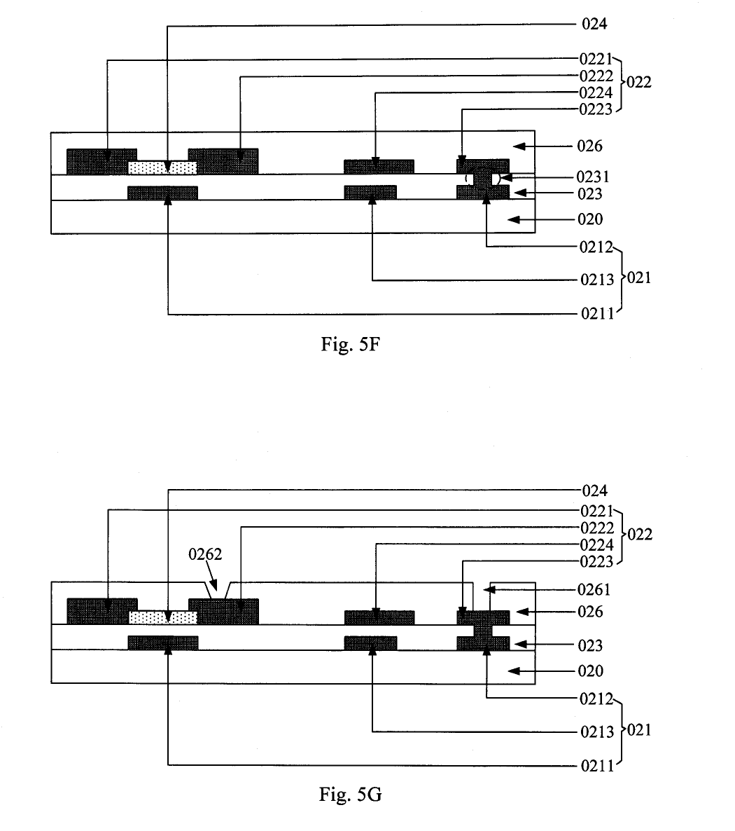

FIG. 5A shows a structural diagram after forming a patterned gate metal layer 021 on the base substrate 020 (step 401) according to the embodiment. Referring to FIG. 5A, the patterned gate metal layer 021 includes a gate electrode 0211 and a first ground wire 0212, and may further include a peripheral signal line 0213. Furthermore, the display substrate 02 may include a display region and a peripheral region. The gate electrode 0211 is located in the display region, and both the first ground wire 0212 and the peripheral signal line 0213 are located in the peripheral region.

As an example, a layer of metal material may be deposited on the base substrate 020 using a process such as coating, magnetron sputtering, thermal evaporation, plasma enhanced chemical vapor deposition (abbreviated as PECVD) or the like to obtain a metal material layer. The metal material layer is processed through a patterning process to obtain a patterned gate metal layer 021. The patterning process may include photoresist coating, exposing, developing, etching and photoresist lifting-off. Therefore, processing a metal material layer through a patterning process comprises: coating a layer of photoresist on the metal material layer; exposing the photoresist with a mask such that the photoresist is formed into a fully exposed area and a non-exposed area; processing with a developing process to remove the photoresist in the fully exposed area and retain the photoresist in the non-exposed area; etching an area of the metal material layer corresponding to the fully exposed area; lifting off the photoresist in the non-exposed area after etching to obtain a patterned gate metal layer 021.

It is noted that the embodiment is described by taking, as an example, the formation of the patterned gate metal layer 021 using positive photoresist. In actual applications, negative photoresist may be used to form the patterned gate metal layer 021. Herein detailed description will not be made in the embodiment of the disclosure.

Step 402: forming a gate insulating layer on the patterned gate metal layer and the base substrate.

FIG. 5B shows a structural diagram after forming a gate insulating layer 023 on the patterned gate metal layer 021 and the base substrate 020 (step 402) according to the embodiment. The gate insulating layer 023 may be formed of an organic resin material. A thickness of the gate insulating layer 023 may be set according to actual needs. No restriction is made to this in the embodiments of the disclosure.

As an example, a layer of organic resin material may be deposited on the patterned gate metal layer 021 and the base substrate 020 through a process of coating, magnetron sputtering, thermal evaporation, PECVD or the like, and is baked to form a gate insulating layer 023.

Step 403: forming a first via in the gate insulating layer.

FIG. 5C shows a structural diagram after forming a first via 0231 in the gate insulating layer 023 (step 403) according to the embodiment. Referring to FIG. 5C, a depth direction (not shown in Fig. SC) of the first via 0231 is perpendicular to an upper surface of the base substrate 020, and an orthographic projection of the first via 0231 onto the base substrate 020 is within a region of an orthographic projection of the first ground wire 0212 onto the base substrate 020, which facilitates the connection of a second ground wire that is to be subsequently formed with the first ground wire 0212. As an example, the gate insulating layer 023 may be processed through a patterning process to form a first via 0231. Reference can be made to step 401 for the process of processing the gate insulating layer 023 through a patterning process. Herein detailed description will not be made in the embodiment of the disclosure.

Step 404: forming a patterned semiconductor layer on the gate insulating layer.

FIG. 5D shows a structural diagram after forming a patterned semiconductor layer 024 on the gate insulating layer 023 (step 404) according to the embodiment. The patterned semiconductor layer 024 may be formed of an amorphous silicon material, a monocrystalline silicon material or a metal oxide material. The patterned semiconductor layer 024 is located in the display region of the display substrate 02.

As an example, a layer of monocrystalline silicon material may be deposited on the gate insulating layer 023 through a process of coating, magnetron sputtering, thermal evaporation, PECVD or the like to obtain a monocrystalline silicon material layer. The monocrystalline silicon material layer is processed through a patterning process to obtain a patterned semiconductor layer 024. Reference can be made to step 401 for the process of processing the monocrystalline silicon material layer through one patterning process. Herein detailed description will not be made in the embodiment of the disclosure.

Step 405: forming a patterned source/drain metal layer on the patterned semiconductor layer and the gate insulating layer, wherein the patterned source/drain metal layer includes a source electrode, a drain electrode and a second ground wire, wherein the source electrode and the drain electrode are not in contact with each other but are both in contact with the patterned semiconductor layer, and wherein none of the source electrode, the drain electrode and the patterned semiconductor layer is in contact with the second ground wire.

FIG. 5E shows a structural diagram after forming a patterned source/drain metal layer 022 on the patterned semiconductor layer 024 and the gate insulating layer 023 (step 405) according to the embodiment. Referring to FIG. 5E, the patterned source/drain metal layer 022 includes a source electrode 0221, a drain electrode 0222 and a second ground wire 0223, and may further include a peripheral signal line 0224. Both the source electrode 0221 and the drain electrode 0222 are located in the display region of the display substrate 02, and the second ground wire 0223 and the peripheral signal line 0224 are located in the peripheral region of the display substrate 02.

As an example, a layer of metal material may be deposited on the patterned semiconductor layer 024 and the gate insulating layer 023 through a process of coating, magnetron sputtering, thermal evaporation, PECVD or the like to obtain a metal material layer. The metal material layer is then processed through a patterning process to obtain a patterned source/drain metal layer 022. Reference can be made to step 401 for the process of processing the metal material layer through a patterning process. Herein detailed description will not be made in the embodiment of the disclosure.

Step 406: forming an intermediate insulating layer on the patterned semiconductor layer, the patterned source/drain metal layer, and the gate insulating layer.

FIG. 5F shows a structural diagram after forming an intermediate insulating layer 026 on the patterned semiconductor layer 024, the patterned source/drain metal layer 022 and the gate insulating layer 023 (step 046) according to the embodiment. For the process of forming the intermediate insulating layer 026, reference can be made to the process of forming the gate insulating layer 023 in step 402. Herein detailed description will not be made in the embodiment of the disclosure.

Step 407: forming a drain via and a second via in the intermediate insulating layer.

FIG. 5G shows a structural diagram after forming a second via 0261 and a drain via 0262 in the intermediate insulating layer 026 (step 407) according to the embodiment. Referring to FIG. 5G, a depth direction (not shown in FIG. 5G) of the second via 0261 is perpendicular to an upper surface of the base substrate 020. An orthographic projection of the second via 0261 onto the base substrate 020 is within a region of an orthographic projection of the second ground wire 0223 onto the base substrate 020, and an orthographic projection of the drain via 0262 onto the base substrate 020 is within a region of an orthographic projection of the drain electrode 0222 onto the base substrate 020, which facilitates the connection of a third ground wire that is to be subsequently formed with the second ground wire 0223, and the contact of the pixel electrode with the drain electrode 0222. As an example, the intermediate insulating layer 026 may be processed through a patterning process to form the second via 0261 and the drain via 0262. Reference can be made to step 401 for the process of processing the intermediate insulating layer 026 through a patterning process. Herein detailed description will not be made in the embodiment of the disclosure.

Step 408: forming a patterned pixel electrode layer on the intermediate insulating layer, wherein the patterned pixel electrode layer includes a pixel electrode and a third ground wire, wherein the pixel electrode is connected with the drain electrode through the drain via, and wherein the third ground wire is connected with the second ground wire through the second via.

FIG. 3 shows a structural diagram after forming a patterned pixel electrode layer 025 on the intermediate insulating layer 026 (step 408) according to the embodiment. Referring to FIG. 3, the patterned pixel electrode layer 025 includes a pixel electrode 0251 and a third ground wire 0252. The pixel electrode 0251 is connected with the drain electrode 0222 through the drain via, and the third ground wire 0252 is connected with the second ground wire 0223 through the second via 0261. Indium tin oxide (abbreviated as ITO) may be used to form the patterned pixel electrode layer 025.

As an example, a layer of ITO material may be deposited on the intermediate insulating layer 026 through a process of coating, magnetron sputtering, thermal evaporation, PECVD or the like to obtain an ITO material layer. The ITO material layer is processed through a patterning process to obtain a patterned pixel electrode layer 025. Reference can be made to step 401 for the process of processing the ITO material layer through a patterning process. Herein detailed description will not be made in the embodiment of the disclosure.

To sum up, according to the manufacturing method for a display substrate provided by the embodiments of the disclosure, each of at least two electrically conductive layers includes a ground wire, and each ground wire is grounded. Thus static electricity can be guided to the earth via ground wires in at least two electrically conductive layers, which improves antistatic capability of the display substrate and thereby improves antistatic capability of the display panel and the display device including the display substrate.

In the manufacturing method for a display substrate provided by the embodiments of the disclosure, each electrically conductive layer is provided with a ground wire, and ground wires in all electrically conductive layers are connected with one another and one ground wire is grounded, such that all the ground wires form an electrostatic shielding ring covering the display substrate at the periphery of the display substrate. This electrostatic shielding ring can effectively shield static electricity to improve antistatic capability of the display substrate and thereby improves antistatic capability of the display panel and the display device including the display substrate.

The embodiments of the disclosure further provide a display device including the display substrate as shown in FIG. 2 or FIG. 3. The display device may be any product or component having a display function, such as a liquid crystal panel, electronic paper, a mobile phone, a tablet computer, a television, a display, a laptop computer, a digital photo frame, a navigator or the like.

To sum up, the display device provided by the embodiments of the disclosure includes a display substrate. Each of at least two electrically conductive layers of the display substrate includes a ground wire, and each ground wire is grounded. Thus, static electricity can be guided to the earth via ground wires in the at least two electrically conductive layers, which improves antistatic capability of the display substrate and thereby improves antistatic capability of the display device including the display substrate.

Above description is only exemplary embodiments of the disclosure, and does not serve as restrictions on the protection scope of the disclosure. The protection scope of the disclosure is defined by the appended claims.

1. A display substrate, comprising:
a base substrate; and
a plurality of electrically conductive layers insulated from one another on the base substrate, wherein each of at least two of the plurality of electrically conductive layers insulated from one another includes a ground wire, and each ground wire is grounded.

2. The display substrate according to claim 1, wherein
the ground wire in each of the at least two electrically conductive layers is grounded individually.

3. The display substrate according to claim 1, wherein
the ground wires in the at least two electrically conductive layers are connected with one another, and one ground wire in the at least two electrically conductive layers is grounded.

4. The display substrate according to claim 3, further comprising:
an insulating layer between every two adjacent electrically conductive layers of the at least two electrically conductive layers, the ground wires in the at least two electrically conductive layers being connected with one another through a via formed in the insulating layer.

5. The display substrate according to claim 4,
wherein the at least two electrically conductive layers include a patterned gate metal layer and a patterned source/drain metal layer, the patterned gate metal layer being located on the base substrate and including a gate electrode,
wherein the display substrate further comprises:
a gate insulating layer on the patterned gate metal layer and the base substrate; and
a patterned semiconductor layer on the gate insulating layer,
and wherein the patterned source/drain metal layer is located on the patterned semiconductor layer and the gate insulating layer, the patterned source/drain metal layer including a source electrode and a drain electrode which are not in contact with each other, each of the source electrode and the drain electrode being in contact with the patterned semiconductor layer, none of the source electrode, the drain electrode and the patterned semiconductor layer being in contact with a ground wire in the patterned source/drain metal layer.

6. The display substrate according to claim 5,
wherein the at least two electrically conductive layers further include a patterned pixel electrode layer,
wherein the display substrate further comprises:
an intermediate insulating layer on the patterned semiconductor layer, the patterned source/drain metal layer and the gate insulating layer, the intermediate insulating layer having a drain via formed therein,
and wherein the patterned pixel electrode layer is located on the intermediate insulating layer and includes a pixel electrode connected with the drain electrode through the drain via.

7. The display substrate according to claim 6, wherein
the ground wires in the at least two electrically conductive layers are located in a peripheral region of the display substrate, and wherein the gate electrode, the patterned semiconductor layer, the source electrode, the drain electrode and the pixel electrode are all located in a display region of the display substrate.

8. The display substrate according to claim 4, wherein in the at least two electrically conductive layers, an orthographic projection of the via in the insulting layer on each respective electrically conductive layer onto the base substrate has a region overlapping with an orthographic projection of the ground wire in the respective electrically conductive layer onto the base substrate.

9. The display substrate according to claim 8, wherein in the at least two electrically conductive layers, the orthographic projection of the via in the insulting layer on each respective electrically conductive layer onto the base substrate is within a region of the orthographic projection of the ground wire in the respective electrically conductive layer onto the base substrate.

10. The display substrate according to claim 1, wherein
each of the electrically conductive layers includes a peripheral signal line in a peripheral region of the display substrate.

11. A manufacturing method for a display substrate, comprising:
forming a plurality of electrically conductive layers insulated from one another on a base substrate, wherein each of at least two of the plurality of electrically conductive layers insulated from one another includes a ground wire, and each ground wire is grounded.

12. The manufacturing method according to claim 11, wherein
the ground wire in each of the at least two electrically conductive layers is grounded individually.

13. The manufacturing method according to claim 11, wherein
all ground wires in the at least two electrically conductive layers are connected with one another, and one ground wire in the at least two electrically conductive layers is grounded.

14. The manufacturing method according to claim 13, further comprising:
forming an insulating layer between every two adjacent electrically conductive layers of the at least two electrically conductive layers, and forming a via in the insulating layer, the ground wires in the at least two electrically conductive layers being connected with one another through the via.

15. The manufacturing method according to claim 14,
wherein the at least two electrically conductive layers include a patterned gate metal layer and a patterned source/drain metal layer, the patterned gate metal layer being formed on the base substrate and including a gate electrode,
wherein the manufacturing method further comprises:
forming a gate insulating layer on the patterned gate metal layer and the base substrate; and
forming a patterned semiconductor layer on the gate insulating layer,
and wherein the patterned source/drain metal layer is formed on the patterned semiconductor layer and the gate insulating layer, the patterned source/drain metal layer including a source electrode and a drain electrode which are not in contact with each other, each of the source electrode and the drain electrode being in contact with the patterned semiconductor layer, none of the source electrode, the drain electrode and the patterned semiconductor layer being in contact with a ground wire in the patterned source/drain metal layer.

16. The manufacturing method according to claim 15,
wherein the at least two electrically conductive layers further include a patterned pixel electrode layer,
wherein the manufacturing method further comprises:
forming an intermediate insulating layer on the patterned semiconductor layer, the patterned source/drain metal layer, and the gate insulating layer; and
forming a drain via in the intermediate insulating layer,
and wherein the patterned pixel electrode layer is formed on the intermediate insulating layer and includes a pixel electrode connected with the drain electrode through the drain via.

17. The manufacturing method according to claim 16, wherein
the ground wires in the at least two electrically conductive layers are located in a peripheral region of the display substrate, and wherein the gate electrode, the patterned semiconductor layer, the source electrode, the drain electrode and the pixel electrode are all located in a display region of the display substrate.

18. A display device, comprising the display substrate according to claim 1.

19. A display device, comprising the display substrate according to claim 2.

20. A display device, comprising the display substrate according to claim 3.
